(19) United States
(12) Patent Application Publication
(10) Pub. No.: US 2026/0136905 A1
(43) Pub. Date: May 14, 2026

(54) METHOD OF MANUFACTURING SEMICONDUCTOR DEVICES

(71) Applicant: Samsung Electronics Co., Ltd., Suwon-si (KR)

(72) Inventors: Yunho Kang, Suwon-si (KR); Myungho Kong, Suwon-si (KR); Yeonuk Kim, Suwon-si (KR); Jungmin Park, Suwon-si (KR); Joenggi Yun, Suwon-si (KR)

(21) Appl. No.: 19/211,753

(22) Filed: May 19, 2025

(30) Foreign Application Priority Data
Nov. 14, 2024 (KR) 10-2024-0162243

(51) Int. Cl. H01L 21/768

(52) U.S. Cl. CPC H10W 20/089; H10W 20/056; H10W 20/074

(57) ABSTRACT

A method of manufacturing a semiconductor device may include: forming a via in a first interlayer insulating layer, forming a conductive layer on the first interlayer insulating layer and the via, forming a patterned hard mask layer on the conductive layer, forming a first interconnection line on the via and second interconnection lines spaced apart from the first interconnection line in a first direction by partially removing the conductive layer using the patterned hard mask layer as a first mask, and forming a recessed via by partially removing the via by atomic layer etching (ALE) using the patterned hard mask layer and the first interconnection line as a second mask, where a width of an upper surface of the recessed via in the first direction and a width of a lower surface of the first interconnection line in the first direction are equal.

### CROSS-REFERENCE TO RELATED APPLICATION(S)

This application claims the benefit under 35 USC 119(a) of Korean Patent Application No. 10-2024-0162243 filed on Nov. 14, 2024 in the Korean Intellectual Property Office, the entire disclosure of which is incorporated herein by reference for all purposes.

### TECHNICAL FIELD

The present disclosure relates to a method of manufacturing semiconductor devices.

### BACKGROUND

As the demand for high performance, high speed, and/or multifunctionality of semiconductor devices increases, a degree of integration of semiconductor devices is increasing. In manufacturing semiconductor devices having fine patterns in response to the trend toward high integration of semiconductor devices, it is desirable to implement patterns having fine (or smaller) widths or fine (or smaller) separation distances.

### SUMMARY

An aspect of the present disclosure is to provide a method of manufacturing a semiconductor device having improved reliability.

According to example embodiments, a method of manufacturing a semiconductor device may include: forming a via in a first interlayer insulating layer that at least partially exposes an upper surface of the via, forming a conductive layer on the first interlayer insulating layer and the via, forming a patterned hard mask layer on the conductive layer, forming a first interconnection line on the via and second interconnection lines spaced apart from the first interconnection line in a first direction by partially removing the conductive layer using the patterned hard mask layer as a first mask, and forming a recessed via by partially removing the via by atomic layer etching (ALE) using the patterned hard mask layer and the first interconnection line as a second mask, where a width of an upper surface of the recessed via in the first direction and a width of a lower surface of the first interconnection line in the first direction are equal.

According to example embodiments, a method of manufacturing a semiconductor device may include: forming a via, forming interconnection lines including a first interconnection line and second interconnection lines, where the first interconnection line is on the via, where the second interconnection lines are spaced apart from the first interconnection line in a first direction, where the interconnection lines extend in a second direction, perpendicular to the first direction, and where an upper surface of the via is at least partially exposed by the first interconnection line, and forming a recessed via by removing portions of the via that are adjacent to side surfaces of the first interconnection line by atomic layer etching (ALE) using the interconnection lines as a mask, where a portion of each of side surfaces of the recessed via is coplanar with the side surfaces of the first interconnection line.

According to example embodiments, a method of manufacturing a semiconductor device may include: forming a via in a first interlayer insulating layer that at least partially exposes an upper surface of the via, forming an etch stop layer on the first interlayer insulating layer and the via, forming interconnection lines including a first interconnection line and second interconnection lines, where the first interconnection line is on the via and the etch stop layer, and where the second interconnection lines are spaced apart from the first interconnection line in a first direction and are on the etch stop layer, removing an exposed portion of the etch stop layer between the interconnection lines, and forming a recessed via by removing portions of the via by atomic layer etching (ALE) using the interconnection lines as a mask, where the first interlayer insulating layer is not removed while forming the recessed via.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a plan view illustrating a semiconductor device according to example embodiments;

FIG. 2 is a cross-sectional view illustrating a semiconductor device according to example embodiments;

FIGS. 3A and 3B are enlarged views of a portion of a semiconductor device according to example embodiments;

FIGS. 4A and 4B are cross-sectional views illustrating a semiconductor device according to example embodiments;

FIGS. 5A and 5B are cross-sectional views illustrating a semiconductor device according to example embodiments;

FIG. 6 is a cross-sectional view illustrating a semiconductor device according to example embodiments;

FIGS. 7A and 7B are plan views and cross-sectional views illustrating a semiconductor device according to example embodiments;

FIG. 8 is a flow chart for illustrating a method of manufacturing a semiconductor device according to example embodiments; and

FIGS. 9A, 9B, 9C, 9D, and 9E are drawings illustrating a process sequence for illustrating a method of manufacturing a semiconductor device according to example embodiments.

### DETAILED DESCRIPTION

Hereinafter, preferred embodiments of the present disclosure will be described with reference to the accompanying drawings. Hereinafter, it can be understood that terms such as ‘on,’ ‘upper,’ ‘upper portion,’ ‘upper surface,’ ‘below,’ ‘lower,’ ‘lower portion,’ ‘lower surface,’ ‘side surface,’ and the like may be denoted by reference numerals and refer to the drawings, except where otherwise indicated.

To clarify the present disclosure, the same elements or equivalents are referred to by the same reference numerals throughout the specification. Further, since sizes and thicknesses of constituent members shown in the accompanying drawings are arbitrarily given for better understanding and ease of description, the present disclosure is not limited to the illustrated sizes and thicknesses. In the drawings, the thickness of layers, films, panels, regions, etc., are exaggerated for clarity. In the drawings, for better understanding and ease of description, thicknesses of some layers and areas are excessively displayed.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

In addition, unless explicitly described to the contrary, the word “comprises”, and variations such as “comprises” or “comprising”, will be understood to imply the inclusion of stated elements but not the exclusion of any other elements. As used herein, the singular forms “a,” “an” and “the” are intended to include the plural forms as well, unless the context clearly indicates otherwise. The term “and/or” includes any and all combinations of one or more of the associated listed items. The term “connected” may be used herein to refer to a physical and/or electrical connection and may refer to a direct or indirect physical and/or electrical connection. The term “exposed” may be used to define a relationship between particular layers or surfaces, but it does not require the layer or surface to be free of other elements or layers thereon in the completed device. Components or layers described with reference to “overlap” in a particular direction may be at least partially obstructed by one another when viewed along a line extending in the particular direction or in a plane perpendicular to the particular direction. The terms “first,” “second,” etc. may be used herein to merely distinguish one component, element, etc., from another.

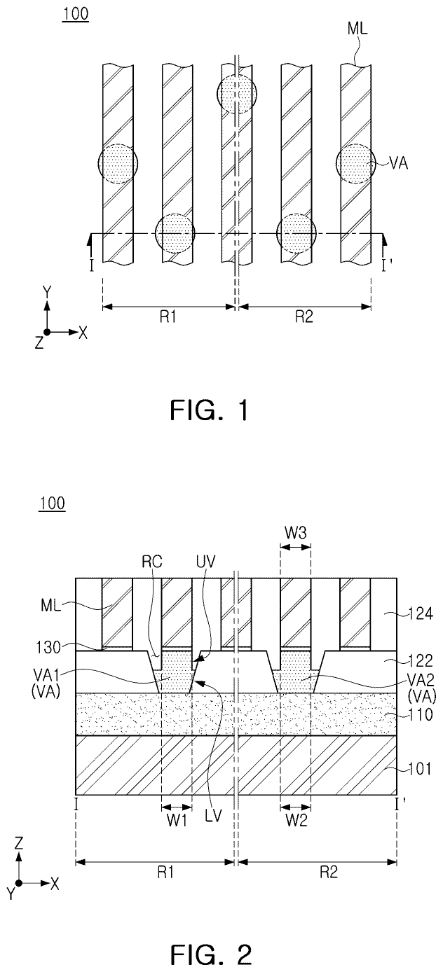

FIG. 1 is a plan view illustrating a semiconductor device according to example embodiments. To help understanding, only some components of a semiconductor device are illustrated in FIG. 1.

FIG. 2 is a cross-sectional view illustrating a semiconductor device according to example embodiments. FIG. 2 illustrates a cross-section of the semiconductor device of FIG. 1 taken along the cutting line I-I′.

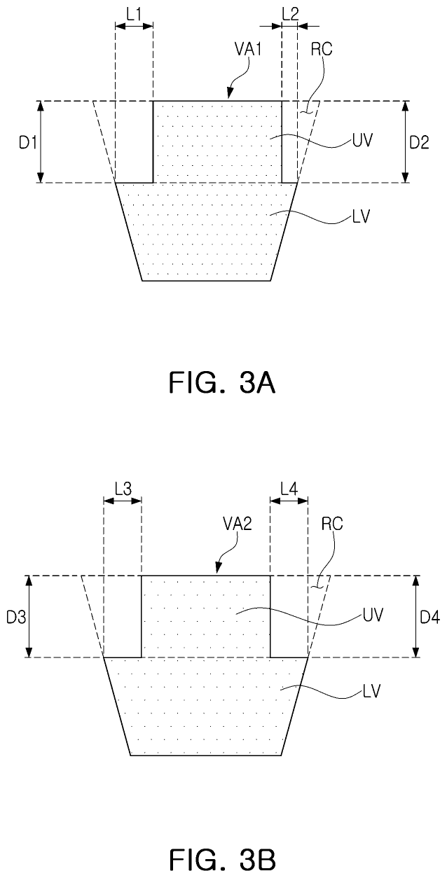

FIGS. 3A and 3B are enlarged views of a portion of a semiconductor device according to example embodiments. FIGS. 3A and 3B are enlarged views of the first and second vias VA1 and VA2 of FIG. 2.

Referring to FIGS. 1 to 3B, a semiconductor device 100 may include a substrate 101, a device layer 110, a first interlayer insulating layer 122 on the device layer 110, vias VA disposed in the first interlayer insulating layer 122, a second interlayer insulating layer 124 on the first interlayer insulating layer 122, interconnection lines ML disposed in the second interlayer insulating layer 124, and etch stop layers 130 on lower surfaces of the interconnection lines ML.

The substrate 101 may have an upper surface extending in an X-direction and a Y-direction. The substrate 101 may include a semiconductor material, such as a group IV semiconductor, a group III-V compound semiconductor, or a group II-VI compound semiconductor. For example, the group IV semiconductor may include silicon, germanium, or silicon-germanium. The substrate 101 may be provided as a bulk wafer, an epitaxial layer, a silicon on insulator (SOI) layer, a semiconductor on insulator (SeOI) layer, or the like. Active regions may be defined in an upper region of the substrate 101, for example, by a device isolation layer.

The device layer 110 may be disposed on the substrate 101, and may include semiconductor elements which are not shown. The device layer 110 may include, for example, at least one of a passive device, a transistor, a memory cell, an interconnection structure, or an insulating layer.

The first interlayer insulating layer 122 may be disposed on the device layer 110, and the second interlayer insulating layer 124 may be disposed on the first interlayer insulating layer 122. The first and second interlayer insulating layers 122 and 124 may be formed of an insulating material, for example, may include at least one of silicon oxide, silicon nitride, or silicon oxynitride. In some example embodiments, at least one of the first interlayer insulating layer 122 or the second interlayer insulating layer 124 may include a plurality of insulating layers.

The vias VA may be disposed in an embedded form within the first interlayer insulating layer 122. Upper surfaces of the vias VA may be at least partially exposed through or by the first interlayer insulating layer 122. The upper surfaces of the vias VA may be coplanar with an upper surface of the first interlayer insulating layer 122. The vias VA may be physically and/or electrically connected to semiconductor elements, such as transistors, in the device layer 110. The vias VA may be electrically connected to interconnection lines ML on the vias VA. For example, the vias VA may be an n^{th} interconnection from the device layer 110, and the interconnection lines ML may be an n+1^{th} interconnection. As illustrated in FIG. 1, the vias VA may at least partially overlap the interconnection lines ML in plan view, and may be disposed below the interconnection lines ML.

The vias VA may include first and second vias VA1 and VA2. The first and second vias VA1 and VA2 may be disposed in first and second regions R1 and R2 of the semiconductor device 100, respectively. The first and second regions R1 and R2 may be regions, which are adjacent to each other or spaced apart from each other. For example, the first region R1 may be an edge region of the semiconductor device 100, and the second region R2 may be a center region, but example embodiments thereof are not limited thereto.

Each of the vias VA may include a lower region LV and an upper region UV on the lower region LV. The upper region UV may be disposed in the form of a protrusion on the lower region LV. The vias VA may have ends recessed from upper portions thereof on side surfaces of the interconnection lines ML, and accordingly, recessed regions RC may be formed on side surfaces of the upper region UV. The recessed regions RC may be at least partially filled with a second interlayer insulating layer 124.

Upper surfaces of the upper regions UV of the first and second vias VA1 and VA2 may have first and second widths W1 and W2, respectively, and the first and second widths W1 and W2 may be substantially equal to each other. The first and second widths W1 and W2 may also be substantially equal to a third width W3 of the interconnection lines ML. In the present specification, ‘substantially equal’ means equal or within a threshold difference resulting from deviations or errors that occur during the process. Side surfaces of the upper regions UV may be coplanar with side surfaces of the etch stop layers 130 and side surfaces of the interconnection lines ML.

As illustrated in FIG. 3A, the first via VA1 of the first region R1 may have recessed regions RC formed on side surfaces thereof in the X-direction, perpendicular to the Y-direction, which may be an extension direction of the interconnection lines ML. In the first via VA1, the widths of the recessed regions RC may be different from each other on side surfaces of the interconnection lines ML. Accordingly, the first via VA1 may have an asymmetrical shape on left and right sides. In the first via VA1, a length of the upper surface of the lower region LV at least partially exposed from or by the upper region UV in the X-direction may be a first length L1 and a second length L2, different from the first length L1, respectively. However, depths D1 and D2 of the recessed regions RC in the Z-direction may be substantially the same as each other on side surfaces of the interconnection line ML. In example embodiments, relative sizes of the first length L1 and the second length L2 and the first and second depths D1 and D2 may be varied.

As illustrated in FIG. 3B, in the second via VA2 of the second region R2, the widths of the recessed regions RC may be the same as each other on side surfaces of the interconnection line ML, and accordingly, a third length L3 and a fourth length L4 in the X-direction, which are lengths of the upper surface of the lower region LV at least partially exposed from or by the upper region UV, may be the same as each other. Third and fourth depths D3 and D4 of the recessed regions RC may also be the same as each other on side surfaces of the interconnection line ML. The third length L3 and the fourth length L4 may be different from the first length L1 and the second length L2, and the third and fourth depths D3 and D4 may be substantially the same as the first and second depths D1 and D2. Accordingly, the second via VA2 may have a symmetrical shape on left and right sides. The first to fourth depths D1, D2, D3, and D4 may be, for example, in a range of about 2 nm to about 20 nm.

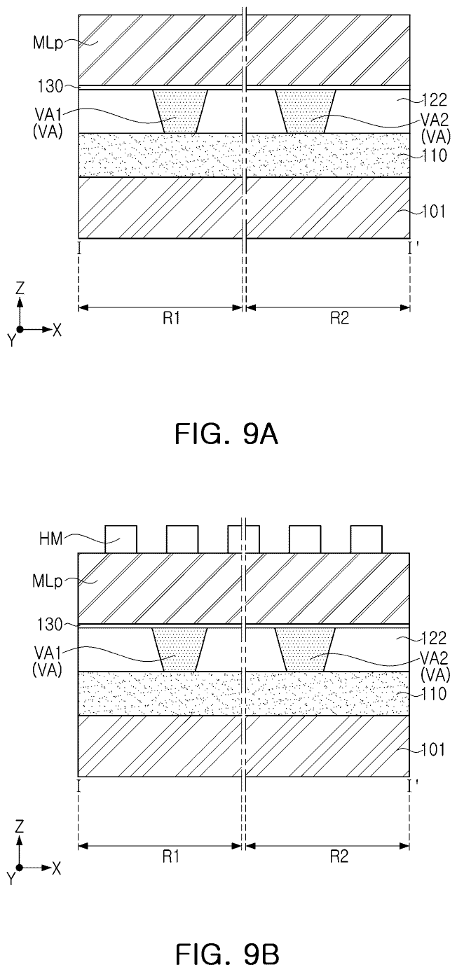

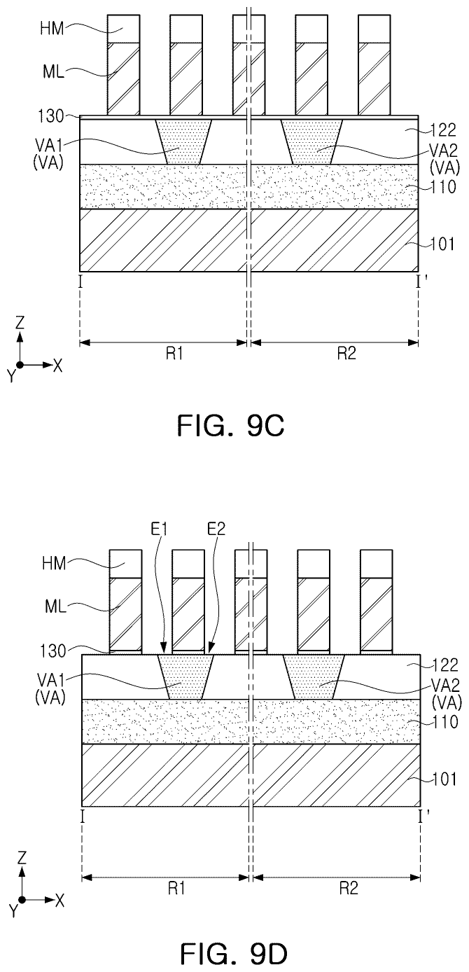

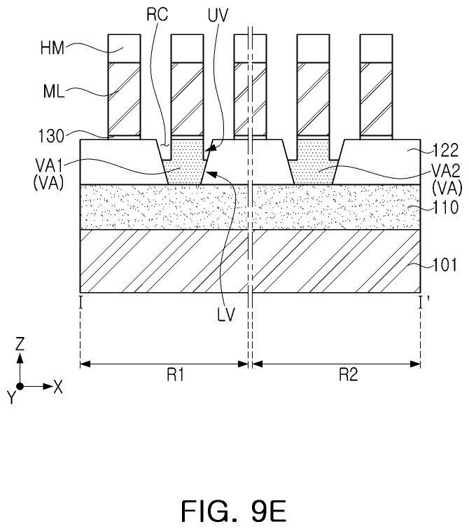

The vias VA may have a structure in which recessed regions RC are formed on side surfaces of interconnection lines ML, so that the vias VA may be reliably electrically separated or insulated from interconnection lines ML, which are not electrically connected, i.e., interconnection lines ML, adjacent to electrically connected interconnection lines ML. Since such recessed regions RC are formed by atomic layer etching (ALE), the recessed regions RC may be formed without damage to the first interlayer insulating layer 122, and the recessed regions RC may be formed at substantially the same depth within the semiconductor device 100 without deviations according to density of the interconnection lines ML, or the like. All of which may be described in more detail with reference to FIGS. 9A to 9E below.

Widths and heights of the vias VA may be, for example, in the range of about 5 mm to about 50 mm, respectively. In some example embodiments, each of the vias VA may include an adhesive layer extending along a bottom surface and side surfaces. In this case, the adhesive layer may be also partially removed due to the recessed regions RC, so that the adhesive layer may remain only in a region extending along the lower surface and side surface of the lower region LV.

The interconnection lines ML may extend, for example, in the Y-direction, on the vias VA, and may be spaced apart from each other in the X-direction. The interconnection lines ML may be electrically connected to the vias VA overlapping in the Z direction. Pitches of the interconnection lines ML, i.e., the sum of the width and the separation distance of the interconnection lines ML (e.g., a pitch between two adjacent interconnection lines may be equal to a sum of the width of one of the two adjacent interconnection lines and the separation distance therebetween, or the pitch may be a distance in the X-direction between centers of the two adjacent interconnection lines), may be in a range of, for example, about 10 nm to about 50 nm. Heights of the interconnection lines ML may be in a range of, for example, about 5 nm to about 50 nm.

In some example embodiments, the interconnection lines ML may have a shape in which the widths thereof increase toward the substrate 101, but example embodiments thereof are not limited thereto, and may also have a shape in which the widths thereof decrease toward the substrate 101. Vias and interconnection lines may be further disposed on the interconnection lines ML.

The vias VA and the interconnection lines ML may include a conductive material, and may include a metal material such as ruthenium (Ru), molybdenum (Mo), tungsten (W), copper (Cu), aluminum (Al), nickel (Ni), titanium (Ti), chromium (Cr), manganese (Mn), iron (Fe), cobalt (Co), and/or the like. The vias VA and the interconnection lines ML may include different materials. For example, the vias VA may include molybdenum (Mo), and the interconnection lines ML may include ruthenium (Ru). In some example embodiments, the vias VA and the interconnection lines ML may include the same material.

The etch stop layers 130 may be disposed to cover or at least partially overlap the lower surfaces of the interconnection lines ML. The etch stop layers 130 may be disposed between the interconnection lines ML and the first interlayer insulating layer 122, and between the interconnection lines ML and the vias VA. The etch stop layers 130 may function as at least one of an etch stop layer when forming interconnection lines ML, an adhesion layer for reinforcing adhesion between the interconnection lines ML and the vias VA, or a diffusion barrier layer.

The etch stop layers 130 may include a conductive material, and may include at least one of a metal, a metal carbide, a metal nitride, a metal boride, or a metal oxide, such as, for example, ruthenium (Ru), molybdenum (Mo), tungsten (W), copper (Cu), aluminum (Al), nickel (Ni), titanium (Ti), chromium (Cr), manganese (Mn), iron (Fe), and cobalt (Co). The etch stop layers 130 may have a relatively thin thickness in the Z-direction, for example, but not limited to, a thickness in the range of about 1 Å to about 100 Å, for example, a thickness in the range of about 3 Å to about 20 Å. However, in some example embodiments, the etch stop layers 130 may be omitted.

In the description of the example embodiments below, any description overlapping the description provided above with reference to FIGS. 1 and 2 is omitted.

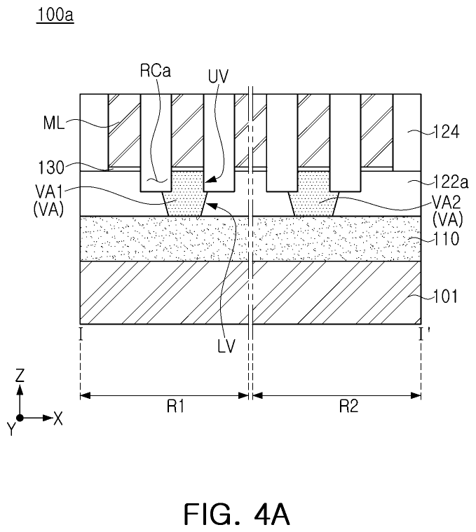

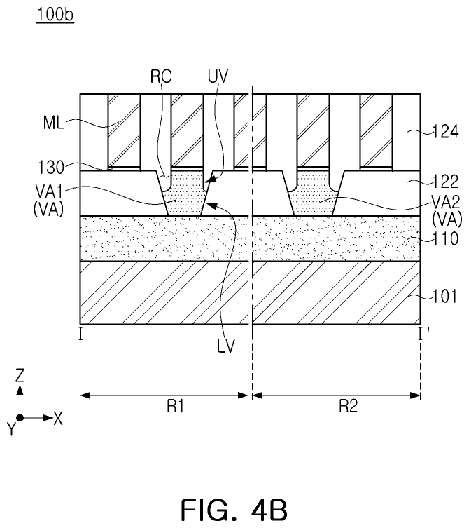

FIGS. 4A and 4B are cross-sectional views illustrating a semiconductor device according to example embodiments. FIGS. 4A and 4B respectively illustrate a region corresponding to FIG. 2.

Referring to FIG. 4A, in a semiconductor device 100a, a portion of a first interlayer insulating layer 122a may also be removed around or adjacent to an upper region UV of the vias VA, so that recessed regions RCa may have an expanded form or a larger area. In the semiconductor device 100a, not only the vias VA but also the first interlayer insulating layer 122a may be recessed around or adjacent to the upper regions UV of the vias VA. Accordingly, the recessed regions RCa may be formed throughout a region between adjacent interconnection lines ML.

By recessing (or at least partially removing) the first interlayer insulating layer 122a, impurities that occur when recessing (or at least partially removing) the vias VA and remain on the surface of the first interlayer insulating layer 122a may be removed, thereby preventing or inhibiting electrical short circuits caused by the impurities. In some example embodiments, the first interlayer insulating layer 122a may be further recessed between the interconnection lines ML in regions that are not adjacent to the vias VA.

Referring to FIG. 4B, in a semiconductor device 100b, the recessed shape of the vias VA may be different from the example embodiments of FIGS. 2 to 3B. Corners between the side surfaces of the upper regions UV in the vias VA and the upper surfaces of the lower regions LV connected to the side surfaces may be curved or nonlinear. In example embodiments, the degree of curvature, the shape of the curvature, and the like may be varied.

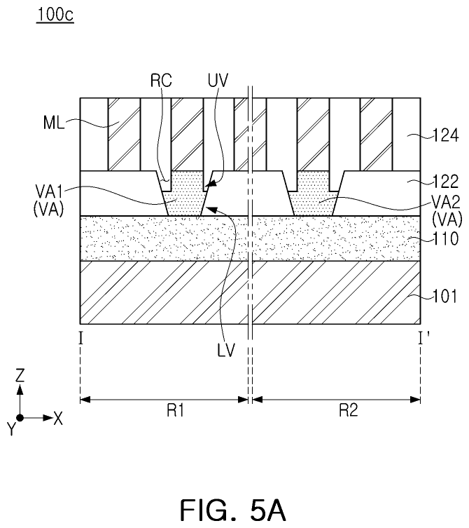

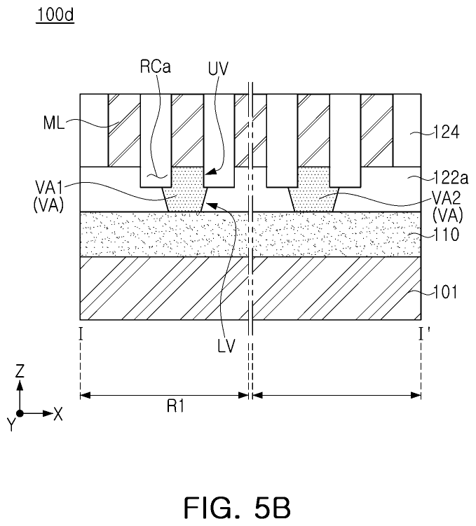

FIGS. 5A and 5B are cross-sectional views illustrating a semiconductor device according to example embodiments. FIGS. 5A and 5B respectively illustrate a region corresponding to FIG. 2.

Referring to FIG. 5A, a semiconductor element 100c may not include etch stop layers 130, unlike the example embodiments of FIGS. 2 to 3B. Accordingly, lower surfaces of the interconnection lines ML may be in contact with the vias VA and the first interlayer insulating layer 122. Depending on a material of the etch stop layers 130, contact resistance between the vias VA and the interconnection lines ML may be lowered when the etch stop layers 130 are not included.

Referring to FIG. 5B, a semiconductor element 100d may not include etch stop layers 130, unlike the example embodiment of FIG. 4A. Otherwise, the description referring to FIG. 4A may be equally applied.

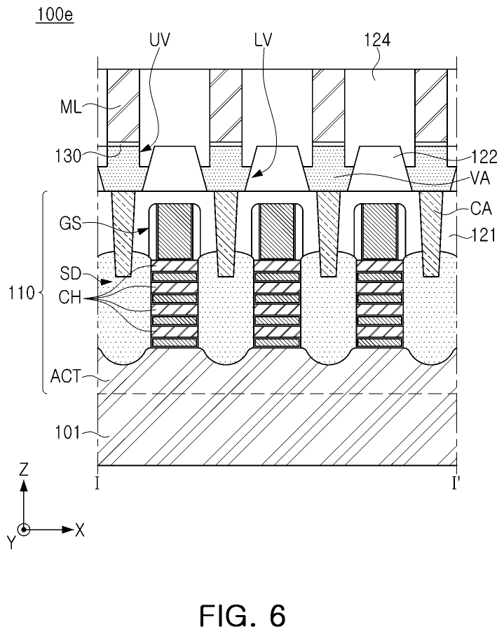

FIG. 6 is a cross-sectional view illustrating a semiconductor device according to example embodiments.

Referring to FIG. 6, in a semiconductor device 100e, the device layer 110 may include an active region ACT, a plurality of channel layers CH disposed to be spaced apart from each other vertically on the active region ACT, gate structures GS extending to intersect the active region ACT and respectively including a gate electrode, source/drain regions SD in contact with the plurality of channel layers CH, contact plugs CA connected to the source/drain regions SD, and a lower interlayer insulating layer 121.

In the device layer 110, the active region ACT has a fin structure, and the gate electrode may be disposed to surround or extend around a plurality of channel layers CH. Accordingly, the device layer 110 may include transistors of a Multi Bridge Channel FET (MBCFET™) structure, which is a gate-all-around type field effect transistor.

The active region ACT may be defined by a device isolation layer, and may be disposed to extend in a first direction, for example, the X-direction. The active region ACT may also be described as a component included within the upper region of the substrate 101. The active region ACT may be formed as a portion of the substrate 101 or may include an epitaxial layer grown from the substrate 101. In example embodiments, the active region ACT may or may not include a well region including impurities.

The gate structures GS may be disposed to extend in a second direction, for example, the Y-direction, intersecting the active region ACT and the plurality of channel layers CH on the active region ACT and the plurality of channel layers CH. Functional channel regions of the transistors may be formed in the active region ACT and/or the plurality of channel layers CH intersecting gate electrodes of the gate structures GS. Each of the gate structures GS may include a gate electrode, gate dielectric layers between the gate electrode and a plurality of channel layers CH, and gate spacer layers on side surfaces of the gate electrode. The gate electrode may include a conductive material, and the gate dielectric layers and the spacer layers may include a dielectric material.

A plurality of channel layers CH may be disposed on the active region ACT in regions in which the active region ACT intersects the gate structures GS. The plurality of channel layers CH may include two or more, for example, four channel layers. The plurality of channel layers CH may be connected to source/drain regions SD. The plurality of channel layers CH may be formed of a semiconductor material.

The source/drain regions SD may be disposed in recessed regions of an upper portion of the active region ACT on side surfaces of the gate structure GS. The source/drain regions SD may be disposed to cover or at least partially overlap the side surfaces in the X-direction of each of the plurality of channel layers CH. The source/drain regions SD may include a semiconductor material and may further include dopants. The source/drain regions SD may be formed of an epitaxial layer.

Contact plugs CA may be connected to the source/drain regions SD and may penetrate through or extend into the lower interlayer insulating layer 121 on the source/drain regions SD, and may apply an electrical signal to the source/drain regions SD. The contact plugs CA may be disposed in a form in which the source/drain regions SD are partially recessed, but example embodiments thereof are not limited thereto. The contact plugs CA may include a conductive material. In some example embodiments, each of the contact plugs CA may include a metal silicide layer disposed at a lower end including the lower surface, and may further include a barrier layer. An interconnection structure such as a contact plug may be further disposed on the gate structures GS.

The vias VA may be disposed within the first interlayer insulating layer 122 on the contact plugs CA, and may connect the contact plugs CA and the interconnection lines ML. The descriptions provided above with reference to FIGS. 1 to 3B may be equally applied to the vias VA and the interconnection lines ML.

In FIG. 6, as an example of the device layer 110, a case in which the device layer 110 includes transistors of a MBCFET™ structure is illustrated, but the semiconductor elements disposed in the device layer 110 are not limited thereto.

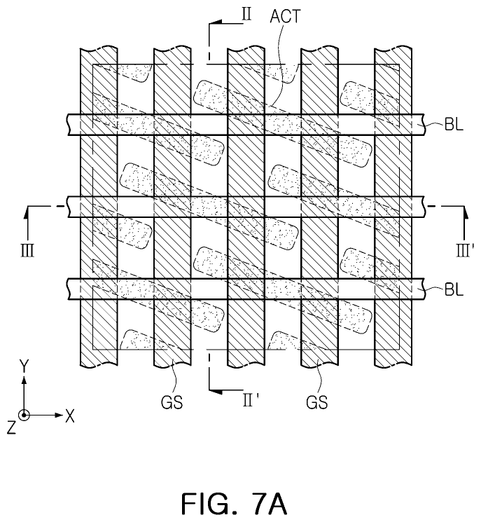

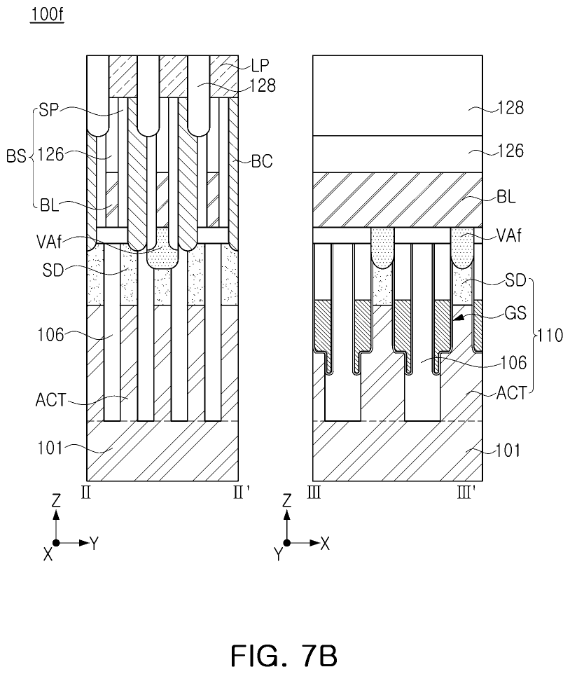

FIGS. 7A and 7B are plan views and cross-sectional views illustrating semiconductor devices according to example embodiments. FIG. 7B illustrates cross-sections of the semiconductor device of FIG. 7A taken along cutting lines II-II′ and III-III′.

Referring to FIGS. 7A and 7B, in a semiconductor device 100f, a device layer 110 may include active regions ACT, a device isolation layer 106 defining the active regions ACT, source/drain regions SD on the active regions ACT, and gate structures GS. The semiconductor device 100f may further include vias VAf, interconnection structures BS including bit lines BL, cell contact structures BC, insulating isolation structures 128, and landing pads LP. The semiconductor device 100f may be a memory device, for example, a DRAM device including DRAM memory cells.

The active regions ACTs may be disposed to extend in a direction intersecting X-and Y-directions and spaced apart from each other in an extension direction and a direction perpendicular thereto, as illustrated in FIG. 7A. The active regions ACT are defined in a portion of the substrate 101 by the device isolation layer 106, and may have a shape protruding or extending from the substrate 101. The device isolation layer 106 includes an insulating material, and may be formed by a shallow trench isolation (STI) process.

Source/drain regions SD may be disposed on the active regions ACT, and may include impurities. The source/drain regions SD may be formed by implanting impurities into a portion of the active regions ACT, and may include a semiconductor material.

Gate structures GS may be embedded within the active regions ACT and may extend across the active regions ACT and into the device isolation layer 106 in the Y-direction. Each of the gate structures GS may include a gate electrode, a gate dielectric layer, and a gate capping layer on the gate electrode. The gate electrode may form a word line of a semiconductor device 100f. The gate electrode may include a conductive material, and the gate dielectric layer and the gate capping layer may include a dielectric material.

The interconnection structures BS may be bitline structures, and each of the interconnection structures BS may include a bitline BL, an interconnection capping layer 126 on the bitline BL, and insulating spacers SP on side surfaces of the bitline BL and the interconnection capping layer 126. The bitlines BL may extend in the X-direction, intersecting the active regions ACT and the gate structures GS on the active regions ACT and the gate structures GS. In some example embodiments, the bit lines BL may include multiple conductive layers. The interconnection capping layer 126 and the insulating spacers SP may include an insulating material.

The vias VAf are disposed below the bit lines BL, and may electrically connect the source/drain regions SD and the bit lines BL. In addition thereto, the description of the vias VA and the interconnection lines ML described above with reference to FIGS. 1 to 3B may be equally applied to the vias Vaf and the bit lines BL, respectively.

Cell contact structures BC are disposed on side surfaces of the interconnection structures BS, and may electrically connect the source/drain regions SD and landing pads LP. The cell contact structures BC include a conductive material, and may include a plurality of layers including, for example, polycrystalline silicon, silicide, and a metal material.

The landing pads LP may overlap at least a portion of the interconnection structures BS and may be electrically connected to the cell contact structures BC. For example, the landing pads LP may be electrically connected to capacitor structures disposed thereabove, which are not shown. The landing pads LP may include a conductive material. Insulating isolation structures 128 may be disposed between the landing pads LP and may extend downwardly.

In FIGS. 7A and 7B, as an example of the device layer 110, a case in which the device layer 110 includes a DRAM device is illustrated, but semiconductor elements disposed in the device layer 110 are not limited thereto. In some example embodiments, the shape of the vias VA described above with reference to FIGS. 1 to 3B may be applied to vias forming an interconnection structure above the landing pads LP, instead of vias connected to the bit lines BL.

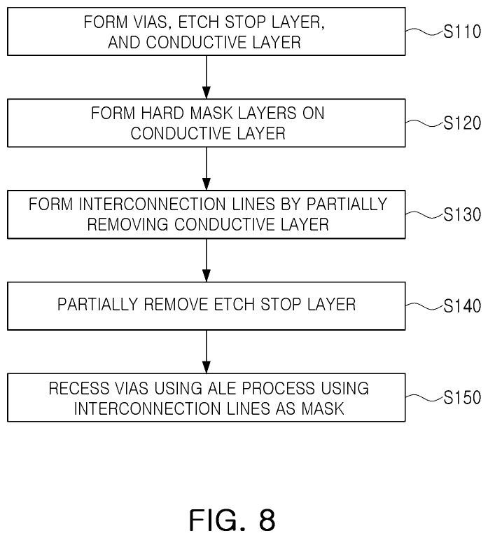

FIG. 8 is a flowchart illustrating a method of manufacturing a semiconductor device according to example embodiments.

FIGS. 9A to 9E are drawings illustrating a process sequence for illustrating a method of manufacturing a semiconductor device according to example embodiments. FIGS. 9A to 9E illustrate example embodiments of a manufacturing method for manufacturing the semiconductor device of FIG. 2.

Referring to FIGS. 8 and 9A, vias VA, an etch stop layer 130, and a conductive layer MLp may be formed (S110).

First, a substrate structure including vias VA embedded in a first interlayer insulating layer 122 having upper surfaces that at least partially exposes the upper surfaces of the vias VA may be prepared. The substrate structure may further include a substrate 101 and a device layer 110 on the substrate 101. According to example embodiments, the substrate structure may further include interconnection lines on the device layer 110. The vias VA may be formed, for example, by partially removing the first interlayer insulating layer 122 to form via holes, depositing a conductive material in the via holes, and then performing a planarization process such as a chemical mechanical polishing (CMP) process. The deposition process may be performed by an atomic layer deposition (ALD) or chemical vapor deposition (CVD) process. The vias VA may be formed so that upper surfaces thereof are exposed, and levels or heights of the upper surfaces relative to the upper surface of the substrate 101 in the Z-direction may be substantially the same.

Next, an etch stop layer 130 and a conductive layer MLp may be sequentially formed on the first interlayer insulating layer 122 and vias VA. The etch stop layer 130 may be deposited with a relatively small thickness, and the conductive layer MLp may be deposited on the etch stop layer 130. In some example embodiments, such as the embodiments of FIGS. 5A and 5B, the operation of forming the etch stop layer 130 may be omitted.

Referring to FIGS. 8 and 9B, patterned hard mask layers HM may be formed on a conductive layer MLp (S120).

Hard mask layers HM may be formed on regions corresponding to the interconnection lines ML of FIG. 2 by being patterned by a photolithography process and an etching process. The hard mask layers HM may include, for example, at least one of silicon oxide, silicon nitride, or silicon carbide.

Referring to FIGS. 8 and 9C, the hard mask layers HM may be used as a mask to partially remove a conductive layer MLp to form interconnection lines ML (S130).

The conductive layer MLp may be partially removed by etching, for example, using reactive ion etching (RIE), ALE, or wet etching. For example, a process time may be relatively shortened by etching the conductive layer MLp using RIE. For example, when materials of the vias VA and the conductive layer MLp, i.e., the interconnection lines ML, are the same and the etch stop layer 130 is not formed, an etching end point in time may be controlled more accurately by etching the conductive layer MLp using ALE.

The interconnection lines ML may be formed to at least partially overlap the vias VA disposed below the interconnection lines ML. The interconnection lines ML on a first via VA1 of the first region R1 may be formed to be offset in the X-direction from the first via VA1 (e.g., the center of the interconnection line on the first via VA1 and the center of the first via VA1 are misaligned and/or free from overlap in the X-direction). This may be because, for example, when vias VA and/or interconnection lines ML are formed, in a photolithography process, the vias VA and the interconnection lines ML are not aligned.

Referring to FIGS. 8 and 9D, an etch stop layer 130 may be partially removed (S140).

The etch stop layer 130 may be removed from the exposed regions through an etching process. The etching process may be, for example, a RIE, ALE, or wet etching process. In some example embodiments, the etching process may be a different method from the etching method of the conductive layer MLp. For example, the conductive layer MLp may be removed by RIE and the etch stop layer 130 may be removed by ALE, but example embodiments thereof are not limited thereto.

Thereby, first and second ends E1 and E2 of the vias VA may be exposed on side surfaces of the interconnection lines ML. The widths in the X-direction of the first and second ends E1 and E2 may be different in the first via VA1 and the second via VA2.

Referring to FIGS. 8 and 9E, vias VA (e.g., upper surfaces of the vias VA) may be recessed using an ALE process using interconnection lines ML as a mask (S150).

The exposed vias VA between the interconnection lines ML may be etched and removed layer by layer from upper surfaces of the vias VA by ALE. The vias VA may be recessed from the upper surfaces of the first and second ends E1 and E2 of FIG. 9D, and a recessed depth, i.e., depths of the recessed regions RC in the Z-direction, may be substantially constant, regardless of the widths of the first and second ends E1 and E2. Thereby, the vias VA may be recessed into the form as described above with reference to FIGS. 1 to 3B.

By using ALE, vias VA may be selectively removed with respect to the first interlayer insulating layer 122 (e.g., the interlayer insulating layer 122 may not be removed while the vias VA are removed during the ALE process). While performing an etching process, the heights of the upper surfaces of the recessed vias VA may be substantially lowered while remaining flat, but example embodiments thereof are not limited thereto. For example, when the vias VA include molybdenum (Mo), the ALE process can be performed by alternately supplying ozone (O₃) and thionyl chloride (SOCl₂) to oxidize and remove molybdenum (Mo) at an atomic layer level, thereby performing the etching process.

In some embodiments, by recessing (or at least partially removing) vias VA using ALE as described above, damage to the first interlayer insulating layer 122 around the vias VA may be minimized, thereby preventing or inhibiting a defect of electrical short circuit due to damage to the first interlayer insulating layer 122, and the depth at which the vias VA are recessed in the Z-direction may be substantially constant. For example, the recess dispersion according to the position at the wafer level or within the semiconductor device, and/or the recess dispersion according to the separation distance between the interconnection lines ML and the alignment dispersion between the interconnection lines ML and the vias VA may be minimized, so that the vias VA may be recessed to a uniform depth.

In some example embodiments, after recessing (or at least partially removing) the vias VA, a heat treatment process or a reduction process may be further performed to remove impurities or oxide layers on the surfaces of the vias VA. In some example embodiments, including the example embodiments of FIGS. 4A and 5B, recessing (or at least partially removing) a portion of the first interlayer insulating layer 122 around or adjacent to the upper regions UV of the vias VA by ALE may be further performed. The first interlayer insulating layer 122 may be recessed in regions between the interconnection lines ML.

Next, referring to FIG. 2 together, the hard mask layers HM may be removed, and a second interlayer insulating layer 124 may be formed on the vias VA and the interconnection lines ML. The second interlayer insulating layer 124 may at least partially fill the recessed regions RC. Thereby, the semiconductor device 100 of FIGS. 1 and 2 may be manufactured.

As set forth above, according to the present disclosure, a method of manufacturing a semiconductor device having improved reliability may be provided by recessing (or at least partially removing) a via using an optimized process to secure a separation distance between the via and an upper interconnection line adjacent to the via.

The various advantages and effects of the present disclosure are not limited to the above-described content, and can be more easily understood through description of specific embodiments of the present disclosure.

While example embodiments have been illustrated and described above, it will be apparent to those skilled in the art that modifications and variations could be made without departing from the scope of the present disclosure as defined by the appended claims.

What is claimed is:

1. A method of manufacturing a semiconductor device, comprising:
forming a via in a first interlayer insulating layer that at least partially exposes an upper surface of the via;
forming a conductive layer on the first interlayer insulating layer and the via;
forming a patterned hard mask layer on the conductive layer;
forming a first interconnection line on the via and second interconnection lines spaced apart from the first interconnection line in a first direction by partially removing the conductive layer using the patterned hard mask layer as a first mask; and
forming a recessed via by partially removing the via by atomic layer etching (ALE) using the patterned hard mask layer and the first interconnection line as a second mask,
wherein a width of an upper surface of the recessed via in the first direction and a width of a lower surface of the first interconnection line in the first direction are equal.

2. The method of claim 1, wherein forming the recessed via by partially removing the upper surface of the via further comprises partially removing first and second ends of the via, and wherein depths of the first and second ends of the via in a second direction that is perpendicular to the first direction are equal.

3. The method of claim 2, wherein widths of the first and second ends of the via in the first direction are different from each other.

4. The method of claim 1, wherein the first interlayer insulating layer is not removed while forming the recessed via.

5. The method of claim 1, further comprising:
partially removing a portion of the first interlayer insulating layer adjacent to an upper region of the recessed via by ALE, after partially removing the via.

6. The method of claim 5, wherein the portion of the first interlayer insulating layer is between the first interconnection line and two of the second interconnection lines that are adjacent to the first interconnection line in the first direction.

7. The method of claim 1, further comprising:
forming an etch stop layer on the first interlayer insulating layer and the via, before forming the first interconnection line and the second interconnection lines; and
partially removing the etch stop layer, after forming the interconnection lines.

8. The method of claim 7, wherein the etch stop layer is partially removed by ALE.

9. The method of claim 7, wherein the etch stop layer comprises at least one of a metal, a metal carbide, a metal nitride, a metal boride, or a metal oxide.

10. The method of claim 1, wherein the first interconnection line and the second interconnection lines comprise different metal materials from the via.

11. The method of claim 1, wherein the conductive layer is partially removed by reactive ion etching (RIE).

12. The method of claim 1, wherein the forming the via comprises:
forming a via hole by partially removing the first interlayer insulating layer; and
depositing a conductive material in the via hole.

13. A method of manufacturing a semiconductor device, comprising:
forming a via;
forming interconnection lines comprising a first interconnection line and second interconnection lines, wherein the first interconnection line is on the via, wherein the second interconnection lines are spaced apart from the first interconnection line in a first direction, wherein the interconnection lines extend in a second direction, perpendicular to the first direction, and wherein an upper surface of the via is at least partially exposed by the first interconnection line; and
forming a recessed via by removing portions of the via that are adjacent to side surfaces of the first interconnection line by atomic layer etching (ALE) using the interconnection lines as a mask,
wherein a portion of each of side surfaces of the recessed via is coplanar with the side surfaces of the first interconnection line.

14. The method of claim 13, wherein the first interconnection line is offset from the via in the first direction, and
recessed regions of the recessed via have different widths in the first direction and a same depth in the second direction.

15. The method of claim 13, wherein the via comprises molybdenum (Mo), and the ALE comprises providing ozone (O₃) and thionyl chloride (SOCl₂) to the via.

16. The method of claim 13, wherein a depth of the recessed via in the second direction is in a range of about 2 nm to about 20 nm.

17. The method of claim 13, wherein a pitch between two of the interconnection lines in the first direction is in a range of about 10 nm to about 50 nm.

18. A method of manufacturing a semiconductor device, comprising:
forming a via in a first interlayer insulating layer that at least partially exposes an upper surface of the via;
forming an etch stop layer on the first interlayer insulating layer and the via;
forming interconnection lines comprising a first interconnection line and second interconnection lines, wherein the first interconnection line is on the via and the etch stop layer, and wherein the second interconnection lines are spaced apart from the first interconnection line in a first direction and are on the etch stop layer;
removing an exposed portion of the etch stop layer between the interconnection lines; and
forming a recessed via by removing portions of the via by atomic layer etching (ALE) using the interconnection lines as a mask,
wherein the first interlayer insulating layer is not removed while forming the recessed via.

19. The method of claim 18, wherein the removing of the exposed portion of the etch stop layer is performed using an etching method different from an etching method of the forming of the interconnection lines.

20. The method of claim 18, wherein a portion of a side surface of the recessed via, a side surface of the etch stop layer, and a side surface of the first interconnection line are coplanar.
